(19) United States
(12) Patent Application Publication
(10) Pub. No.: US 2004/0086661 A1
(43) Pub. Date: May 6, 2004

(54) Sintering of bioactive glass with localised electromagnetic and/or acoustic energy

(76) Inventors: Antti Yli-Urpo, Littoinen (FI); Heimo Ylänen, Turku (FI); Niko Moritz, Turku (FI); Hanni Ato, Turku (FI); Mikko Hupa, Turku (FI)

Correspondence Address: James C Lydon, Suite 100, 100 Daingerfield road, Alexandria, VA, 22314, US

(21) Appl. No.: 10/472,092

(22) PCT Filed: Mar. 12, 2002
(86) PCT No.: PCT/FI02/00191

(30) Foreign Application Priority Data
Mar. 16, 2001 (FI) 20010524

(51) Int. Cl. C23C 14/28

(52) U.S. Cl. 427/595; 427/600

(57) ABSTRACT

The object of the invention is to provide a method for sintering bioactive glass or bioactive glass composite. The method according to the invention is characterised in that the sintering is performed with a localised electromagnetic and/or acoustic energy. Other objects of the invention are a method for coating a device with bioactive glass or bioactive glass composite and a method for attaching at least two devices. All these methods use sintering with localised electromagnetic and/or acoustic energy.

The object of the invention is to provide a method for sintering bioactive glass or bioactive glass composite, a method for coating a device with bioactive glass or bioactive glass composite and a method for attaching at least two devices.

An aim of the invention is to provide a method for manufacturing different devices of bioactive glass and bioactive glass composites. The devices may be for example implants that will resorb and be replaced by the patients own tissue (for example bone). The cements and glues used i.e. in dental medicine to attach an implant made of bioactive glass may not be used since they do not resorb. Furthermore, as cement disintegrates in the high temperatures needed to sterilise an implant, it thus loses its mechanical properties. Another aim of the invention is to provide for a manufacturing method that does not affect the biological activity of the device.

An example of such a manufacturing method is disclosed in the patent publication U.S. Pat. No. 5,490,962. Said publication presents a method for preparation of medical devices by solid free-form fabrication methods. One example of said method is selective laser sintering (SLS). The method consists of sintering a mixture of biocompatible polymer and a biologically active agent.

### BRIEF DESCRIPTION OF THE INVENTION

The invention relates to a method for sintering bioactive glass or bioactive glass composite, in which method the sintering is performed with a localised electromagnetic and/or acoustic energy. The invention also relates to a method for coating a device with bioactive glass or bioactive glass composite. Said method is characterised in that at least one layer of bioactive glass or bioactive glass composite is deposited on the surface of the device and that each said layer is sintered with localised electromagnetic and/or acoustic energy prior to the deposition of another layer of bioactive glass or bioactive glass composite.

The invention further relates to a method for attaching at least two devices, in which method the joint between said at least two devices is formed by sintering bioactive glass or bioactive glass composite present in the location of the joint with localised electromagnetic and/or acoustic energy.

### DETAILED DESCRIPTION OF THE INVENTION

The invention relates to a method for sintering bioactive glass or bioactive glass composite, said method being characterised in that the sintering is performed with localised electromagnetic and/or acoustic energy.

By bioactive material, it is meant a material that has been designed to induce specific biological activity.

In all the methods according to this invention, the electromagnetic and/or acoustic energy may be selected from energies that can be localised, such as different laser irradiations, infra-red irradiation, ultraviolet irradiation, X-ray irradiation, microwave irradiation, ultrasound waves, gamma-irradiation, radioactivity, electron beam irradiation, acoustic waves, pressure waves and particle beam irradiation. It is obvious that the choice of the electromagnetic and/or acoustic energy is determined by the bioactive glass system used.

The irradiations and/or waves are preferably used as impulses, whose frequency, intensity and advancement speed may be varied according to the result to be obtained.

The advantage of using localised electromagnetic and/or acoustic energy is that sintering can be stimulated locally. Sintering can also be performed in a short period of time/surface area and in some cases it is possible to use lower vacuums than with the prior art techniques. This is advantageous for example in the case that a titanium-based device needs to be coated with bioactive glass or attached to another device. Titanium oxidizes very quickly in high temperatures and therefore the sintering time needs to be minimised. Another advantage of the invention is that by using filters or scanning of the irradiation and/or waves, a defined pattern can be made on the device or coating to be sintered. Yet another advantage of the invention is that the heat expansion coefficients of the used materials are not critical.

The advantage of sintering materials with electromagnetic and/or acoustic energy or energies is to avoid raising the temperature and therefore avoid destroying organic or other temperature-sensitive components. The dissolution rate of the material in tissue is also fairly easily controllable.

The bioactive glass composite according to this invention may comprise different materials such as polymers, metals or ceramics. In uses in which the device needs to dissolve, it is preferable to use for example biopolymers. Either polymers based on renewable raw materials, e.g. cellulose, or synthetic polymers that are biodegradables, e.g. polylactides are meant by “biopolymer”. The term “biodegradable” in this context means that it is degradable upon prolonged implantation when inserted in the mammal body. By biomaterial, it is meant a non-viable material used in a medical device, intended to interact with biological systems.

The additives or reinforcements used in the composites may be in various forms such as fibres, woven or nonwoven mats, particles or hollow particles. They may also be porous or dense materials, and it is obvious that they are preferably biocompatibles. By biocompatibility it is meant the ability of a material to perform with an appropriate host response in a specific application.

The invention also relates to a method for coating a device with bioactive glass or bioactive glass composite, characterised in that at least one layer of bioactive glass or bioactive glass composite is deposited on the surface of the device and that each said layer is sintered with localised electromagnetic and/or acoustic energy prior to the eventual deposition of another layer of bioactive glass or bioactive glass composite.

The surface to be coated may optionally be roughened in order to increase the surface of contact between the device and the coating. Same electromagnetic and/or acoustic energies may be used as above.

When the bioactive glass layer is treated according to the invention, the glass melts, thus forming micro-spheres solidly attached to the underlying surface of the device. The coating is formed of small micro-spheres of bioactive glass closely situated to each other and the result is a very thin layer of bioactive glass. A thick coating is preferably obtained by repeating the process a sufficient number of times.

According to an embodiment of the invention, the thickness of the layer of bioactive glass or bioactive glass composite deposited on the surface of the device at one time is from 1 μm to 4000 μm, preferably from 10 μm to 500 μm, more preferably from 20 μm to 100 μm.

According to another embodiment of the invention, the average particle size of the bioactive glass deposited on the surface of the device is from 10 m to 2000 μm, preferably from 20 μm to 400 μm, more preferably from 30 μm to 300 μm. It is obvious to one skilled in the art that the particles may be in any desired form, that is for example spherical, cubic or fibrous form or prepared by crushing.

Tooth-implants, hip-implants, knee-implants, mini plates, external fixation pins, stents (e.g., for use in repair of blood vessels), or any other metallic, polymeric, ceramic or organic implants can be coated with a bioactive glass layer. The coating dissolves in the tissue while a good adhesion between the tissue and the implant is formed, that is, the coating resorbs and is replaced by the patient's own tissue.

The invention further relates to a method for attaching at least two devices, which method is characterised in that the joint between said at least two devices is formed by sintering bioactive glass or bioactive glass composite present in the location of the joint with localised electromagnetic and/or acoustic energy. Said devices may consist of any known material such as metals, polymers or ceramics. According to an embodiment of the invention, at least one of the devices has been coated or at least one of the devices is manufactured with bioactive glass or bioactive glass composite. The different embodiments of this method are discussed further below.

It is obvious to one skilled in the art that the inventive method may also be used to simply attach materials to each other, such as two different materials in the form of particles, wherein the resulting material is a composition of these two materials in the form of particles and of the bioactive glass forming the matrix. Said different materials may also be different kinds of bioactive glasses, and it is thus possible to form a device having different biological activities on different parts of the device.

The invention can also be used for modifying the biological activity of bioactive glass or bioactive glass composite, wherein at least a portion of the surface of bioactive glass or bioactive glass composite is irradiated with a localised electromagnetic and/or acoustic energy.

The devices of the invention may be in various forms, e.g., in the form of a particle, a disc, a film, a membrane, a tube, a hollow particle, a coating, a sphere, a semi sphere, or a monolith, and they may have various applications.

### DESCRIPTION OF THE DRAWINGS

The invention is further illustrated in the following drawings that show some embodiments of the invention.

FIG. 1 illustrates coating of a device according to a first embodiment of the invention.

FIG. 2 illustrates coating of a device according to a second embodiment of the invention.

FIG. 3 illustrates attachment of two devices according to a third embodiment of the invention.

FIG. 4 illustrates attachment of two devices according to a fourth embodiment of the invention.

FIG. 5 illustrates attachment of two devices according to a fifth embodiment of the invention.

FIG. 6 illustrates attachment of two devices according to a sixth embodiment of the invention.

FIG. 7 illustrates attachment of two devices according to a seventh embodiment of the invention.

FIG. 8 illustrates modification of the biological activity of bioactive glass.

FIG. 9 shows a scanning electron microscopy (SEM) image of the attachment of two devices according to the invention.

FIG. 10 shows a SEM back scattering image of bioactive glass sintered according to the invention.

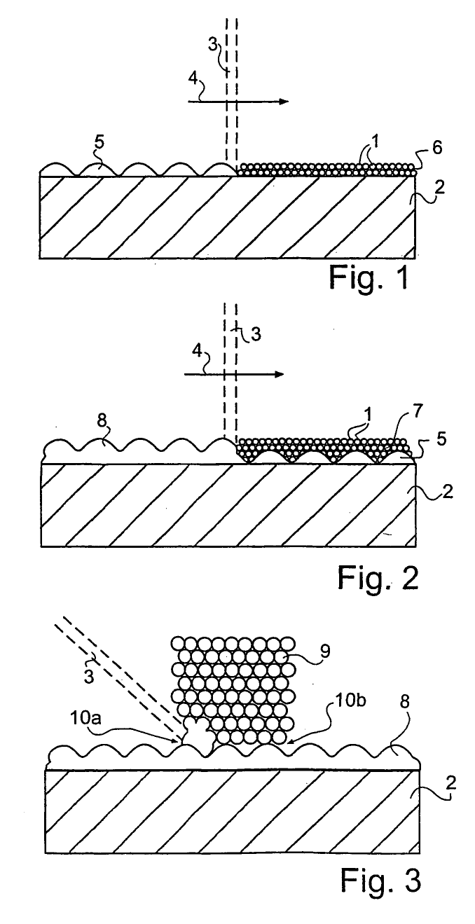

In FIG. 1, a layer 6 of essentially spherical bioactive glass particles 1 is deposited on the surface of a device 2. This layer is then scanned with CO₂-laser beam 3 in the direction indicated by the arrow 4 and under the effect of the laser beam, a sintered coating 5 is formed on the surface of the device 2, according to this first embodiment of the invention.

In FIG. 2, the device 2 coated according to the embodiment shown in FIG. 1 is further coated with a second layer of bioactive glass. A second layer 7 of bioactive glass particles 1 is deposited on the first layer of coating 5 and the second layer 7 is then scanned with CO₂-laser beam 3 in the direction indicated by the arrow 4. Thus a thicker layer 8 of sintered bioactive glass is obtained than in the first embodiment shown in FIG. 1.

FIG. 3 shows attachment of two devices to each other according to the third embodiment of the invention. The first device to be attached is the device 2 coated according to the second embodiment of the invention as shown in FIG. 2. The second device 9 to be attached is manufactured from bioactive glass. A CO₂-laser beam 3 is first directed to the junction 10a of the two devices, where a solid joint is formed under the effect of the laser beam. Then the CO₂-laser beam 3 is directed to the junction 10b to form a solid joint (not shown). The devices 2 and 9 are thereby attached together.

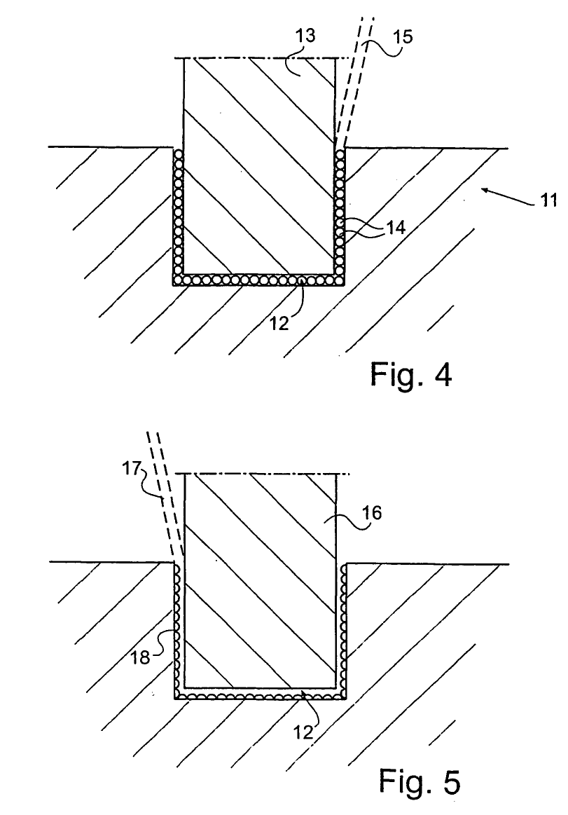

In FIG. 4, attachment of two devices according to a fourth embodiment of the invention is illustrated. The first device 11 comprises a slot 12 in which the second device 13 is to be attached. When the second device 13 is positioned in the slot 12, the space between then is filled with bioactive glass 14 and sintered with infrared irradiation 15.

FIG. 5 illustrates attachment of two devices according to a fifth embodiment of the invention. The first device 11 comprises a slot 12 in which the second device 16 is to be attached. In this embodiment, the surface 18 of the slot 12 has been coated with bioactive glass in such a manner that the bioactive glass is only partially sintered. The sintering is finished once the second device 16 is in its final position and in this embodiment, the sintering is performed with ultraviolet irradiation 17.

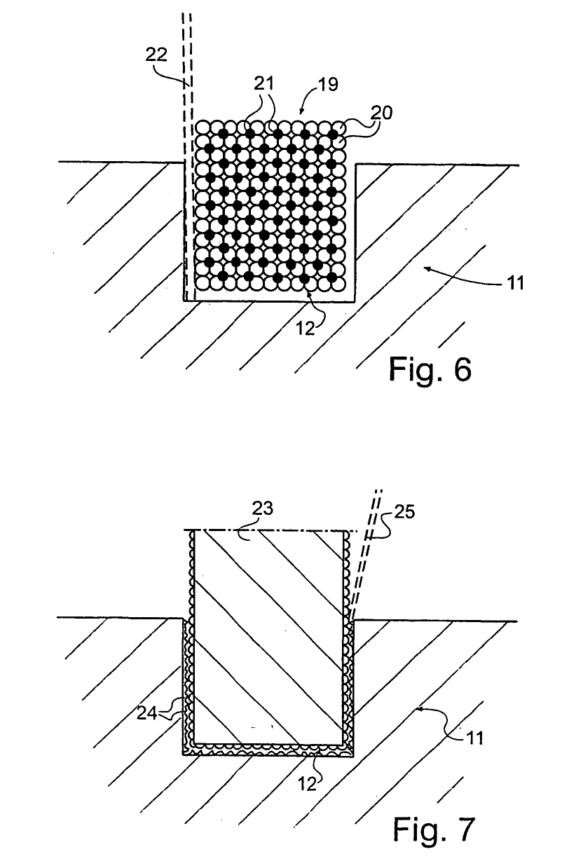

In FIG. 6, attachment of two devices according to a sixth embodiment of the invention is illustrated. The first device 11 comprises a slot 12 in which the second device 19 is to be attached. The second device 19 consists of bioactive glass particles 20 and of reinforcing fibres 21. The reinforcing fibres 21 have all been positioned parallel to each other and perpendicular to the plane of the Figure. The surface of the device 19 consists essentially of the bioactive glass. The device 19 is placed in the slot 12 and the joint is made with X-ray irradiation 22.

In FIG. 7, attachment of two devices according to a seventh embodiment of the invention is illustrated. The first device 11 comprises a slot 12 in which the second device 23 is to be attached. Said second device 23 has been coated with bioactive glass as shown in FIG. 1 and once the device 23 is placed in the slot 12, the remaining gap is filled with crushed particles 24 of bioactive glass. The joint is formed under the action of microwave irradiation 25.

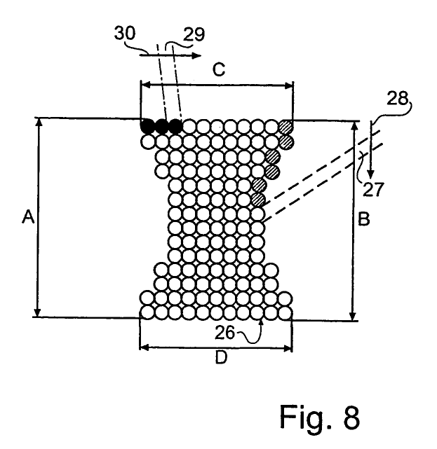

FIG. 8 shows modification of the biological activity of a bioactive glass. A desired portion of the surface of a device 26 that has been previously sintered is treated with ultra-sound irradiation 27. In this embodiment, the portions A and B of the surface are treated by scanning the ultra-sound irradiation 27 in the direction 28 on portion B and correspondingly on portion A of the surface. The portions C and D of the surface of the same device 26 are treated with infra-red irradiation 29 in the direction 30 on portion C and correspondingly on portion D of the surface. In this way, a different biological activity is obtained in portions A and B of the surface than in the portions C and D of the surface.

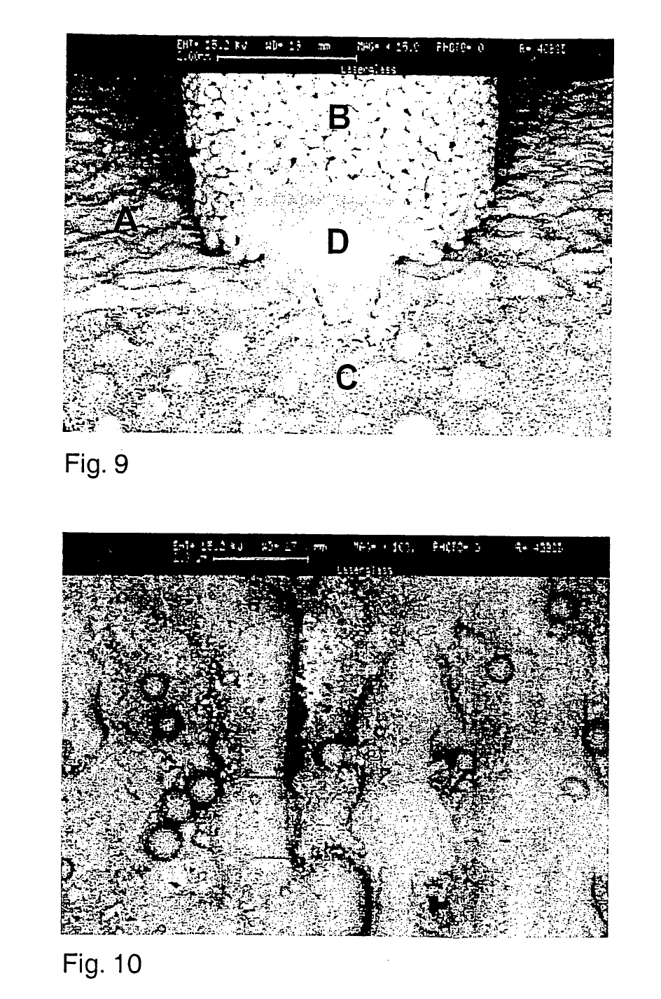

FIG. 9 shows a scanning electron microscopy (SEM) image of the attachment of two devices according to the invention. The different parts of the image are marked by letters A-D, wherein part A is coated by sintered bioactive glass in the form of blobs, part B is a device made of bioactive glass, part C is covered by non-sintered bioactive glass powder (diameter of 45-90 μm) and part D is the attachment point of the two devices.

FIG. 10 shows a SEM back scattering image of bioactive glass sintered according to the invention. The white dots reveal the formation of calcium phosphate due to the reaction of the bioactive glass with body fluid, thus showing its bioactivity. This calcium phosphate is similar to bone mineral.

1. A method for sintering bioactive glass or bioactive glass composite, characterised in that the sintering is performed with localised electromagnetic and/or acoustic energy.

2. Method according to claim 1, characterised in that the localised electromagnetic and/or acoustic energy is selected from the group consisting of laser irradiation, infrared irradiation, ultraviolet irradiation, visible light, X-ray irradiation, microwave irradiation and ultrasound waves.

3. Use of the method of claim 1 for the manufacture of devices consisting essentially of bioactive glass or bioactive glass composites.

4. A method for coating a device with bioactive glass or bioactive glass composite, characterised in that at least one layer of bioactive glass or bioactive glass composite is deposited on the surface of the device and that each said layer is sintered with a localised electromagnetic and/or acoustic energy prior to the optional deposition of another layer of bioactive glass or bioactive glass composite.

5. Method according to claim 4, characterised in that the thickness of the layer of bioactive glass or bioactive glass composite deposited on the surface of the device is from 1 m to 4000 μm, preferably from 10 μm to 500 μm, more preferably from 20 μm to 100 μm.

6. Method according to claim 4 or 5, characterised in that the localised electromagnetic and/or acoustic energy is selected from the group consisting of laser irradiation, infrared irradiation, ultraviolet irradiation, visible light, X-ray irradiation, microwave irradiation and ultrasound waves.

7. A method for attaching at least two devices, characterised in that the joint between said at least two devices is formed by sintering the bioactive glass or bioactive glass composite present in the location of the joint with localised electromagnetic and/or acoustic energy.

8. Method according to claim 7, characterised in that at least one of the devices has been coated according to any of the claims 4-6.

9. Method according to claim 7 or 8, characterised in that at least one of the devices is manufactured from bioactive glass or bioactive glass composite.

10. Method according to any of claims 7-9, characterised in that the localised electromagnetic and/or acoustic energy is selected from the group consisting of laser irradiation, infra-red irradiation, ultraviolet irradiation, visible light, X-ray irradiation, microwave irradiation and ultrasound energy.
